(19) United States
(12) Patent Application Publication
(10) Pub. No.: US 2002/0024118 A1
(43) Pub. Date: Feb. 28, 2002

(54) Semiconductor device having a capacitor and a fabrication process thereof

(75) Inventors: Katsuaki Okoshi, Kawasaki (JP); Masayuki Higashimoto, Kawasaki (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Fujitsu Limited, Kawasaki (JP)

(21) Appl. No.: 09/793,771

(22) Filed: Feb. 27, 2001

(30) Foreign Application Priority Data
Aug. 31, 2000 (JP) 2000-264356

(51) Int. Cl. H01L 27/108; H01L 21/31; H01L 21/8242; H01L 21/318

(52) U.S. Cl. 257/649; 257/639; 257/760; 257/296; 438/744; 438/769; 438/791; 438/239

(57) ABSTRACT

An SiN film is formed by applying a thermal nitridation process to a surface of a Si substrate to form a first SiN film and then forming a second SiN film on the first SIN film by conducting a CVD process that uses SiCl₄ and an ammoniac gas, wherein the CVD process is conducted at a temperature in the range of 550-660° C.

### CROSS-REFERENCE TO RELATED APPLICATION

The present application is based on Japanese priority application No.2000-264356 filed on Aug. 31, 2001, the entire contents of which are hereby incorporated by reference.

### BACKGROUND OF THE INVENTION

The present invention generally relates to semiconductor devices and more particularly to a semiconductor device having a monolithic capacitor and a fabrication process thereof.

Integrated circuits of DRAMs or DRAM/logic hybrid devices generally use a monolithic capacitor that is formed integrally on a common substrate of the integrated circuit.

With continuing trend of device miniaturization in the field of semiconductor devices, monolithic capacitors used in semiconductor integrated circuits are also subjected to miniaturization. In order to maintain necessary capacitance in such extremely miniaturized monolithic capacitors, it has been practiced, in advanced, sub-quarter micron or deep sub-quarter micron semiconductor devices characterized by a gate length of 0.25 μm or less, to reduce the thickness of the capacitor insulation film as much as possible.

Conventionally, a so-called ONO structure has been used extensively for a capacitor insulation film of DRAMs, wherein an ONO structure includes an SiN film having a large dielectric constant sandwiched by a pair of SiO₂ films. A typical ONO film includes an SiO₂ film formed on a lower electrode of polysilicon by a thermal oxidation process and an SiN film deposited thereon by a CVD process. Further, the CVD-SiN film thus deposited is subjected to a thermal oxidation process and a thin SiO₂ film is formed on the top surface of the CVD-SiN film as a result of the thermal oxidation process. Such an ONO film has an advantageous feature of relatively large dielectric constant and low defect density.

On the other hand, such conventional ONO films have a drawback, in view of the construction thereof that uses a pair of low-dielectric SiO₂ films at respective upper and lower sides of the SiN film, in that the advantage of using the high-dielectric SiN film is canceled out more or less.

Thus, efforts have been made in recent ultrafine semiconductor integrated circuits to provide a high-quality SiN film directly on a lower Si electrode.

For example, Japanese Laid-Open Patent Publications 5-36899, 9-50996 and 11-8359 describe a process of forming a high-quality SIN film by the steps of: forming a high-quality SiN film on a lower electrode of Si by applying thereto a thermal nitridation process at a high temperature of 690-700° C.; and depositing a CVD-SIN film thereon at a high temperature of about 700° C. while using SiH₂Cl₂, SiHCl₃ or SiCl₄ as a gaseous source of Si.

According to such a prior art process, it becomes possible to obtain a capacitor having a superb electrical characteristic, provided that the capacitor insulation film has a thickness of 4.0 nm or more. Further, Japanese Laid-Open Patent Publication 2000-10082 describes an SiN capacitor insulation film having an SiO₂-equivalent thickness, which is the thickness of the capacitor insulation film represented in terms of the thickness of an electrically equivalent SiO₂ film, of 0.38 nm, by conducting a CVD process at 700° C. while using SiCl₄ as the source gas.

This conventional process of forming an SiN film, however, has a drawback in that the deposition has to be conducted at a high temperature of 700° C. or more. When such a high temperature process is applied to ultrafine semiconductor integrated circuits, there is a substantial risk that the distribution profile of impurity elements already formed in the substrate in correspondence to various active devices may undergo substantial modification and the desired operational characteristic may not be obtained for the active devices.

In more detail, it should be noted that a capacitor of a ultrafine semiconductor device is generally formed on an interlayer insulation film provided on a substrate, while various active devices such as transistors are already formed on the substrate underneath the interlayer insulation film. Typically, such an active device includes a diffusion region that is formed in the substrate by an ion implantation process of an impurity element.

Thus, when a capacitor having an SiN capacitor insulation film is formed on such an interlayer insulation film according to the foregoing prior art process, the high temperature process exceeding 700° C. for forming the SiN capacitor insulation film may induce a substantial modification in the distribution profile of the impurity element. In order to avoid such unwanted modification of the impurity distribution profile, it is necessary to suppress the temperature at the time of forming the SiN film to be 690° C. or less when the semiconductor integrated circuit is formed with the design rule of 0.18 μm. In semiconductor devices formed with more strict design rules, it is preferable to suppress the temperature of the thermal process to be about 650° C. or less.

Thus, there is a demand for a process capable of forming a high quality SiN film at such a low temperature of 650° C. or less.

### SUMMARY OF THE INVENTION

Accordingly, it is a general object of the present invention to provide a novel and useful semiconductor device and fabrication process thereof wherein the foregoing problems are eliminated.

Another and more specific object of the present invention is to provide an ultrafine semiconductor device having a high quality SiN capacitor insulation film and a fabrication process thereof wherein the high quality SiN capacitor insulation film is formed at a substrate temperature of 650° C. or less.

Another object of the present invention is to provide a semiconductor device, comprising:

a substrate;

a device formed on said substrate; and

a capacitor formed on said substrate in electrical connection with said device,

said capacitor having a capacitor insulation film of SiN having a refractive index of approximately 1.90.

According to the present invention, the leakage current through the capacitor insulation film is suppressed substantially, and it becomes possible to reduce the thickness of the capacitor insulation film below about 4.0 nm in terms of the SiO₂-equivalent thickness. By using an SiN film having a reduced thickness for the capacitor insulation film, it becomes possible to secure a large capacitance for the capacitor. According to the present invention, it is possible to form the SiN film of the present invention by a nitridation process and a pyrolytic CVD process conducted at a low temperature of 650° C. or less, wherein the SiN film thus formed has a refractive index of approximately 1.90. By forming the SiN film directly on the lower electrode of Si, which may be any of amorphous silicon or polysilicon or single-crystal silicon, it is possible to form substantially the entire capacitor insulation film by SiN, and the capacitance of the capacitor is successfully and effectively maximized. Of course, the present invention does not exclude the case in which a thin SiO₂ film originating from a native oxide film is interposed between the SiN film and the lower electrode. In view of the fact that the capacitor insulation film of the present invention can be formed at a low temperature, the present invention is particularly useful and effective when used in combination with a device having a gate length of 0.18 μm or less.

Another object of the present invention is to provide a method of fabricating a semiconductor device having a substrate carrying thereon an active device and a capacitor, comprising the steps of:

forming a first SiN film on a surface of a Si pattern constituting a lower electrode of said capacitor by applying a thermal nitridation process to said surface of said Si pattern as a part of a capacitor insulation film of said capacitor;

forming a second SiN film on a surface of said first SiN film as a part of said capacitor insulation film, by conducting a CVD process that uses a reaction of SiCl₄ and an ammoniac gas,

wherein said CVD process is conducted at a temperature in the range of 550-660° C.

According to the present invention, it becomes possible to form a high-quality SiN film at a low temperature of 650° C. or less, and the risk that the distribution profile of an impurity element formed already in the substrate in correspondence to a diffusion region of the active device is eliminated even in such a case the semiconductor device is a ultrafine semiconductor device. By using SiCl₄, which is free from H (hydrogen) in the CVD process of the SiN film, and by controlling the flow-rate of NH₃ such that SiCl₄ and NH₃ are supplied with a flow-rate ratio of 1:1-1:5, in other words by controlling the flow-rate ratio such that supply rate of NH₃ becomes closer to the supply rate of SiCl₄, the amount of H incorporated into the SiN film is minimized and the leakage current is minimized accordingly. By setting the substrate temperature at the time of the CVD process to be 640° C. or less, the deposition rate of the SiN film is decreased and the surface morphology of the SiN film is improved.

Other objects and further features of the present invention will become apparent from the following detailed description when read in conjunction with the attached drawings.

### BRIEF DESCRIPTION OF THE DRAWINGS

FIGS. 1A-1C are diagrams showing the process of forming an SiN film according to a first embodiment of the present invention;

FIG. 2 is a diagram showing the construction of a low-pressure CVD apparatus used in the process of the first embodiment;

FIG. 3 is a flowchart showing the process of forming the SiN film in the first embodiment of the present invention;

FIG. 4 is a diagram showing a temperature profile used in the first embodiment;

FIG. 5 is a diagram showing a leakage characteristic of the SiN film formed according to the temperature profile of FIG. 4;

FIG. 6 is a diagram showing a temperature profile used in a comparative experiment;

FIG. 7 is a diagram showing the construction of a capacitor used in the first embodiment of the present invention for evaluating the property of the SiN film;

FIG. 8 is a diagram showing the relationship between a leakage current through the SiN film and an SiO₂-equivalent thickness thereof;

FIGS. 9A and 9B are diagrams respectively showing distribution profiles of Si in the SiN film according to the first embodiment and in an SiN film formed by the comparative experiment;

FIGS. 10A and 10B are diagrams respectively showing distribution profiles of N in the SiN film according to the first embodiment and in the SiN film of the comparative experiment;

FIGS. 11A and 11B are diagrams respectively showing distribution profiles of O in the SiN film according to the first embodiment and in the SiN film of the comparative experiment;

FIGS. 12A-12F are diagrams showing a fabrication process of a semiconductor integrated circuit according to a second embodiment of the present invention; and

FIGS. 13A-13D are diagrams showing the process between FIGS. 12D and 12E in more detail.

### DETAILED DESCRIPTION OF THE INVENTION

[First Embodiment]

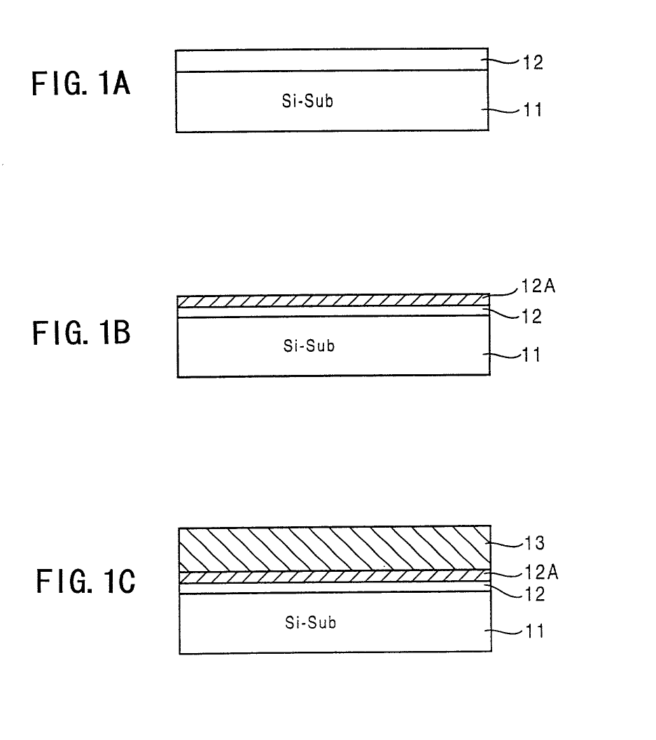

FIGS. 1A-1C show the process of forming an SiN film according to a first embodiment of the present invention.

Referring to FIG. 1A, a Si substrate 11 carrying thereon a native oxide film is subjected to a chemical treatment in a diluted HF solution for removal of the native oxide film therefrom, wherein such a clean surface of the Si substrate 11 is again covered by a thin native oxide film 12 immediately after the foregoing HF treatment process as a result of an oxidation process caused by O₂ or H₂O contained in the environment.

Thus, when an SIN film is deposited directly on such a native oxide film 12 by way of a low-pressure CVD process, there is a tendency, in view of the fact that a native oxide film generally has a natural variation of thickness in the range of several nanometers, and further in view of the fact that the deposition rate of a CVD-SIN film on such a native oxide film is large in the part where the native oxide film is thin while the deposition rate reduces in the part where the native oxide film is thick, in that the thickness variation of the native oxide film 12 is enhanced as a result of the deposition of the CVD-SiN film and the CVD-SiN film cannot provide a smooth and flat surface necessary for a capacitor insulation film.

Thus, in the present embodiment, a step of FIG. 1B is conducted in which the structure of FIG. 1A is subjected to a thermal annealing process conducted under an atmosphere of N₂ with a N₂ pressure of 1.6×104 Pa at 650° C. over a duration not exceeding 120 minutes. As a result of such a thermal annealing process, the native oxide film 12 is partially or entirely converted into a thermal nitride film 12A. The thermal nitride film 12A thus formed has a thickness of 0.9-1.2 nm.

Next, in the step of FIG. 1C, a CVD-SIN film 13 is deposited on the thermal nitride film 12A with such a thickness that the total thickness of the CVD-SiN film 13 and the thermal nitride film 12A has an SiO₂-equivalent thickness of 4 nm or less.

In the step of FIG. 1C, it should be noted that the substrate temperature is set to a range between 550-650° C., and SiC₄ and NH₃ are supplied as the source gases of Si and N with a flow-rate ratio SiCl₄:NH₃ set to the range of 1:1-1:5.

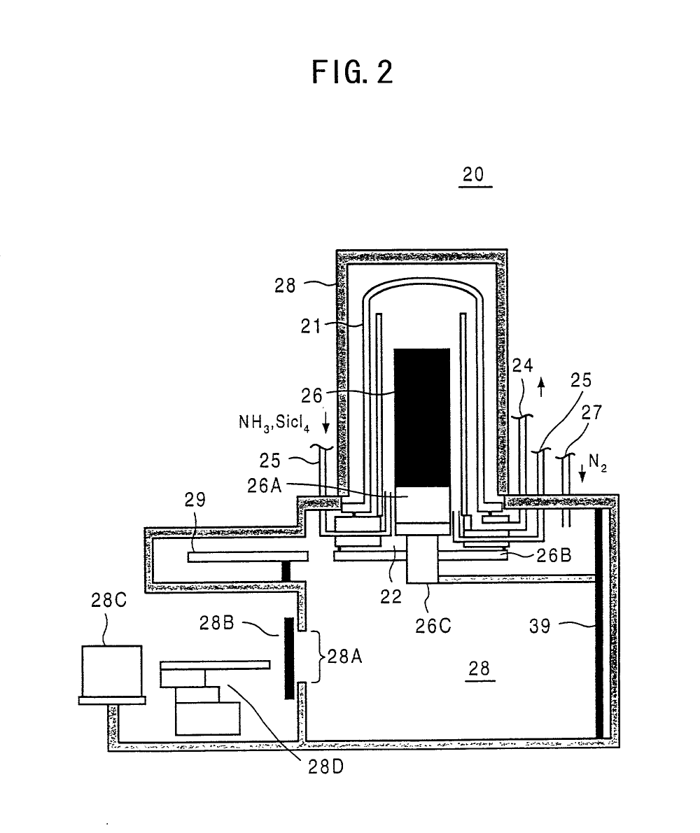

FIG. 2 shows the construction of a low-pressure CVD apparatus 20 used for conducting the step of FIGS. 1A-1C;

Referring to FIG. 2, the low-pressure CVD apparatus 20 includes a quartz reactor tube 21 holding therein a substrate to be processed, wherein the reactor tube 21 has a closed, first end and an open, second end 22 and is covered by a thermal insulator body 23 that includes therein a heater (not illustrated).

The interior of the reactor tube 21 is evacuated by a vacuum pump (not illustrated) via an evacuation port 24, and reaction gases of SiCl₄ and NH₃ are introduced into the interior of the reactor tube 21 via an inlet port 25 as a source gas of Si and a source gas of N respectively.

In the reactor tube 21, the substrate is held, together with other similar substrates to be processed, horizontally on a quartz boat 26 with a mutual separation from one another. These substrates are transported into the interior of the reactor tube 21 and further transported away therefrom via the foregoing open end as the quartz boat 26 is moved in upward and downward directions.

Below the reactor tube 21, there is provided a load-lock chamber 28 supplied with an inert gas such as N₂ via a port 27, wherein the load-lock chamber 28 includes a transport mechanism 26C such that the quartz boat 26 is moved up and down along a guide shaft 26D provided therein. In the state that the quartz boat 26 is up, it should be noted that a bottom plate 26B formed at a bottom part 26A of the quartz boat 26 closes the opening 22 and hence the reactor tube 21. In the state that the quartz boat 26 is down, on the other hand, a gate valve formed at an end of the load-lock chamber 28 rotates so as to close the opening 22.

Further, the load-lock chamber 28 includes, in a part thereof, an opening 28A having a door 28B, and there is provided a cassette 28C and a robot 28D outside the load-lock chamber 28 adjacent to the door 28B, wherein the cassette 28C holds therein the substrate to be processed and the robot 28D carries out transport of the substrate between the cassette 28C and the quartz boat 26 moved to the load lock-chamber 28.

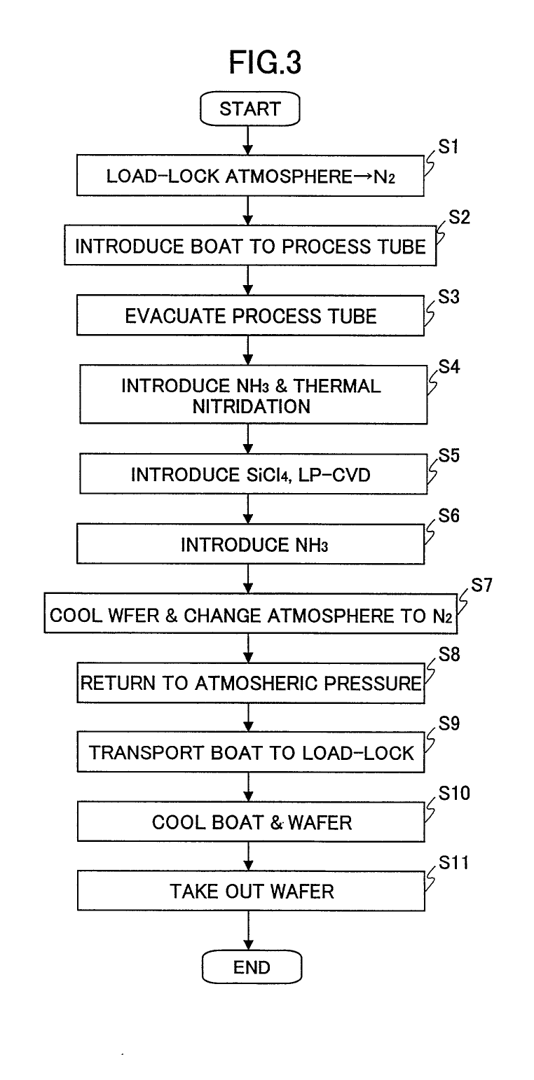

Next, the process of FIGS. 1A-1C conducted by the low-pressure CVD apparatus of FIG. 2 will be explained in detail with reference to a flowchart of FIG. 3. In the description below, it is assumed, unless noted otherwise, that the reactor 21 is held at a temperature of 400° C. and is filled with N₂ with a pressure of 1.0×10⁵ Pa.

Referring to FIG. 3, the quartz boat 26 is moved down in the step S1 by the foregoing transport mechanism 26C to a position below the reactor tube 21, and the opening 22 of the reactor 21 is closed by the gate valve 29.

In this state, a substrate having the structure of FIG. 1A in the cassette 28C is picked up by the robot 28D and is introduced into the load-lock chamber 28 via the door 28B and the opening 28A. The substrate thus introduced is then mounted on the quartz boat 26. Next, the door 28B is closed and the atmosphere in the load-lock chamber 28 is changed to an N₂ atmosphere by introducing N₂ thereto via the port 27 for a duration of about 30 minutes, such that the oxygen concentration level in the N₂ atmosphere becomes less than 10 ppm.

Next, in the step S2, the gate valve 29 is opened and the quartz boat 26 is moved, together with the substrate held thereon, in the upward direction into the reactor tube 21 via the opening 22 by activating the transport mechanism 26C. In the state that the boat 26 is fully up and entered into the reactor tube 21, the bottom plate 26B of the boat 26 closes the opening 22.

Next, in the step S3, the reactor tube 21 is evacuated via the evacuation port 24 until the pressure inside the reactor tube 21 reaches a level of 3.9×10⁻¹ Pa or less.

Next, in the step of S4, an NH₃ gas is introduced into the reactor tube 21 via the inlet tube 25 with a flow-rate of 2 SLM, until the pressure inside the reactor tube 21 reaches a level of 1.6×10⁴ Pa. Further, the temperature of the substrate is increased, from the foregoing initial temperature of 400° C., to a temperature of 640° C. with a rate of 100° C./min while maintaining the foregoing pressure of 1.6×10⁴ Pa. By maintaining the foregoing temperature of 640° C. for 120 minutes, the native oxide film 12 on the Si substrate 11 is converted totally, or at least partially, to SiN, and the thermal nitride film 12A is formed with a thickness of 0.9-1.2 nm.

Next, in the step S5, the pressure inside the reactor tube 21 is set to 26.6 Pa, and NH₃ and SiCl₄ are introduced into the reactor tube 21 via the inlet port 25 with respective flow-rates set to 250 SCCM and 50 SCCM. There, the partial pressure of SiCl₄ in the reactor 21 is maintained to about ⅕ the partial pressure of NH₃. By continuing the supply of SiCl₄ and NH₃ for the duration of 15 minutes, it is possible to form the SiN film 13 such that the sum of the thermal nitride film 12A and the CVD-SiN film 13 becomes about 4 nm.

In the step S5, it should be noted that NH₃ is introduced already into the reactor tube 21 in the step S4 when the SiC₄ gas is introduced in the step S5. Thus, the problem of unwanted deposition of polysilicon film on the substrate is effectively avoided even when the SiCl₄ gas is introduced in the step S5.

Next, in the step S6, the foregoing temperature of 640° C. of the reactor tube 21 is maintained and the supply of the SiCl₄ gas to the reactor tube 21 is interrupted. With the interruption of supply of SiCl₄, the atmosphere in the reactor tube 21 changes to NH₃ in about 3 minutes.

Next, in the step S7, the temperature of the reactor tube 21 is lowered gradually to 400° C. with a transition time of about 15 minutes. When the temperature has reached 400° C., the NH₃ gas is switched to N₂ gas. With this, NH₃ and SiCl₄ remaining in the reactor tube 21 and also in cooperating gas lines are purged, and the atmosphere in the reactor tube 21 returns to the N₂ atmosphere.

Next, in the step S8, the evacuation of the reactor tube 21 via the port 24 is stopped, and the pressure inside the reactor 21 is increased to the level of 1.0×10⁵ Pa.

Next, in the step S9, the quartz boat 26 is lowered, and the quartz boat 26 is transported, together with the substrate on the quartz boat 26, into the load-lock chamber 28. After the quartz boat 26 is thus lowered, the gate valve 29 is driven so as to close the opening 22 of the reactor tube 21.

Next, in the step S10, the substrate is cooled to a room temperature in the load-lock chamber 28 together with the quartz boat 26, and the door 28B is opened in the step S11. Further, the robot 28D picks up the substrate on the quartz boat 26 and returns the same to the cassette 28C.

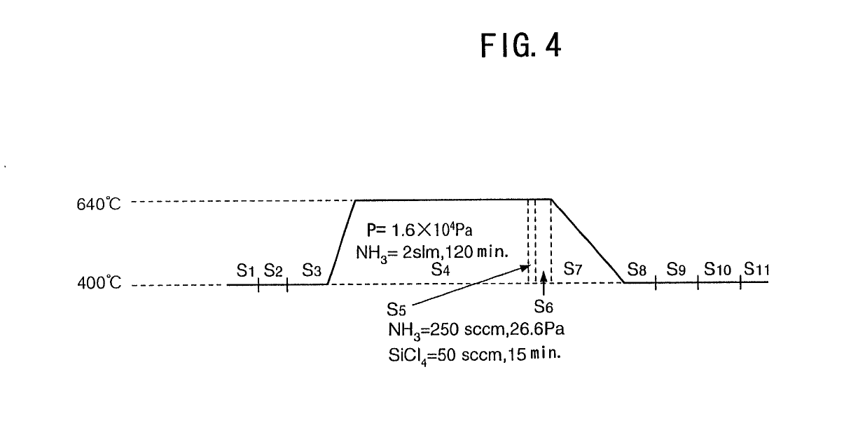

FIG. 4 represents the temperature profile used in the CVD apparatus 20 in the present embodiment in the process steps S1-S11 of FIG. 3.

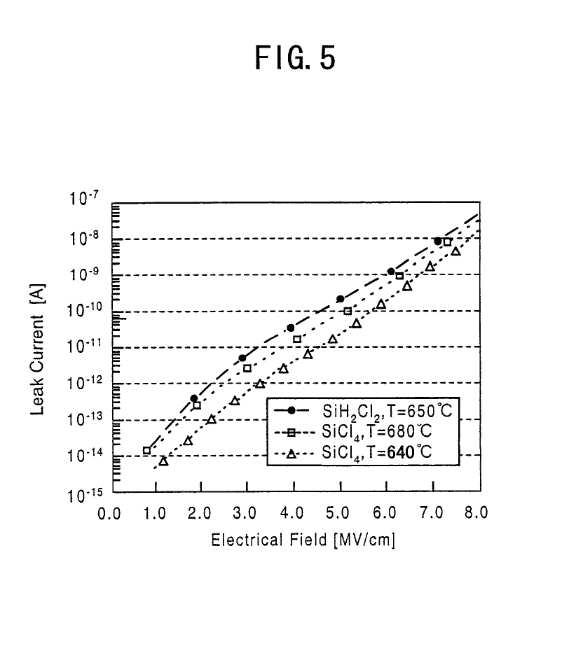

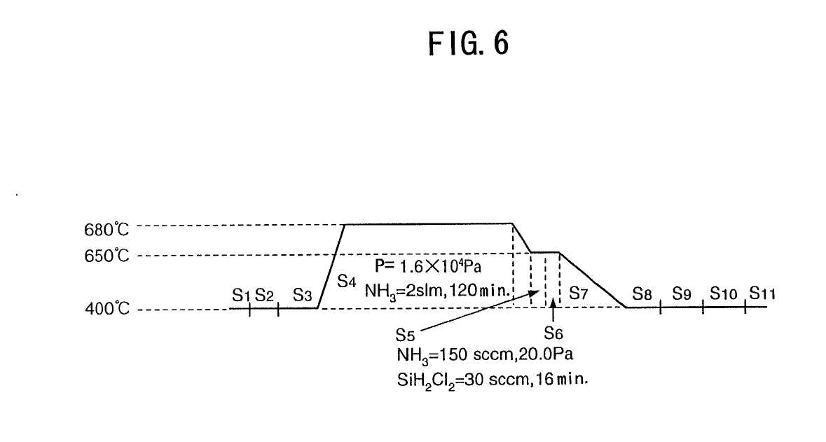

FIG. 5, on the other hand, shows the relationship between the applied electric field and the leakage current for the SiN film of the present embodiment in comparison with a first reference SiN film formed according to a process in which the steps S4-S6 of FIG. 3 are conducted at 680° C. while using SiCl₄ and NH₃ as the respective sources of Si and N. Further, FIG. 5 represents the leakage current for a second reference SiN film in which the thermal nitridation process of the step S4 is conducted at 680° C., followed by a CVD process at 650° C. but using a SiH₂Cl₂ gaseous source in place of SiCl₄ as represented in FIG. 6. In FIG. 5, the result for the present embodiment is represented by Δ while the result for the first reference SiN film is represented by □. Further, the result for the second reference SiN film is represented by ●.

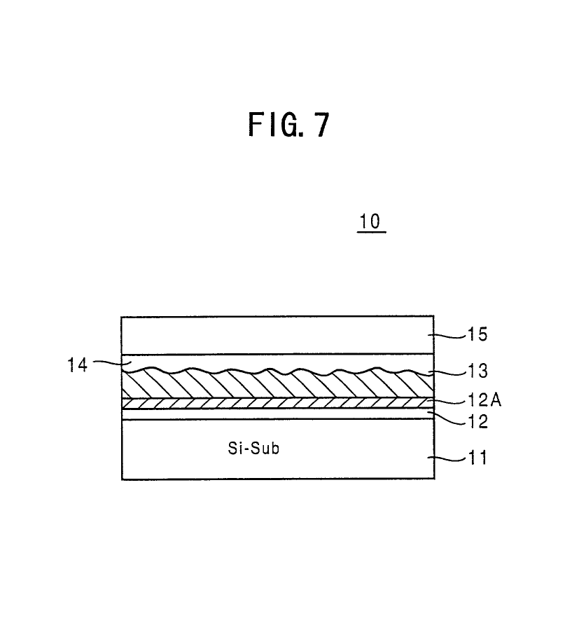

In the experiment of FIG. 5, the leakage current was measured by forming an MOS diode as represented in FIG. 7 and by measuring the leakage current through the MOS diode, wherein the MOS diode is formed by growing an SiO₂ film 14 on the SiN film 13 by conducting a wet oxidation process and further forming a conductive amorphous silicon electrode 15. It should be noted that the SiN film of the present embodiment obtained in the step of FIG. 1C has the SiO₂-equivalent thickness of 3.8 nm.

In the second reference SiN film of FIG. 6 represented by ●, it should be noted that the thermal nitridation process in the step S4 for forming the thermal nitride film 12A is conducted at 680° C. for 120 minutes under the pressure of 1.6×10⁴ Pa while supplying NH₃ at the flow-rate of 2 SLM. In the step 5, the CVD process of the SiN film 13 is conducted at 650° C. for 16 minutes while supplying NH₃ and SiH₂Cl₂ with respective flow-rates of 150 SCCM and 30 SCCM.

Referring to FIG. 5, it can be seen that the leakage current is reduced in the SiN film of the present embodiment substantially as compared with the SiN film of the first reference, by using SiCl₄ for the source of Si and by setting the substrate temperature to 640° C. when depositing the CVD-SiN film 13, as compared with the case of the first reference SiN film in which the CVD process is conducted at the temperature of 680° C. Further, it can be seen that the leakage current is reduced successfully when the CVD-SiN film is formed by a CVD process conducted at the substrate temperature of 640 or 680° C., as long as SiCl₄ is used as the source of Si in place of SiH₂Cl₂. This phenomenon suggests that the use of SiCl₄, which is free from H (hydrogen), reduces the H concentration in the SiN film and the low H concentration in the SiN film thus formed contributes to the decrease of the leakage current through the SiN film.

It is noted that the NH₃ gas used for the source of N does contain H. Thus, the present invention suppresses the partial pressure of NH₃ in the reactor tube 21 to be ⅕ or less than the partial pressure of SiCl₄ for suppressing the incorporation of H as much as possible. As can be seen from FIG. 5, the leakage current of the present embodiment represented by Δ is smaller by a factor of ten or more as compared with the leakage current for the case of the second reference SiN film in the state in which an electric field of 2.5 MV/cm, which is usual in practical semiconductor devices, is applied to the SiN film. As noted previously, the results of FIG. 5 are all obtained for the case in which the SiN films have the SiO₂-equivalent thickness of 3.8 nm.

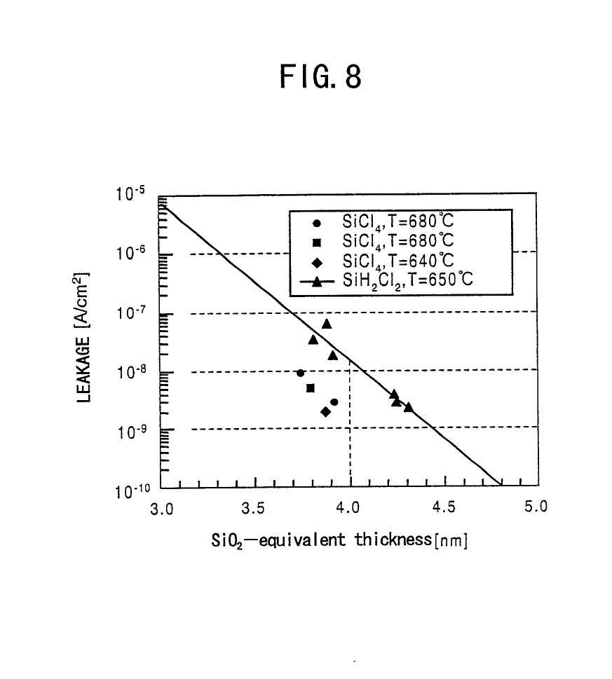

FIG. 8 represents the relationship between the leakage current through the SiN film and the SiO₂-equivalent thickness thereof.

Referring to FIG. 8, it can be seen that the leakage current through the SiN film increases generally linearly with decrease of the SiO₂-equivalent thickness of the SiN film. When the SiN film of the second reference (SiH₂Cl₂, T=650° C.) is used for the capacitor insulation film 13, it can be seen that an SiO₂-equivalent thickness exceeding 4.0 nm would be needed in order to suppress the leakage current density to the level of 10⁻⁸ A/cm² or less as represented in FIG. 8 by ▴. It should be noted that the leakage current density of 10⁸ A/cm² or less is required in recent ultrafine semiconductor devices.

When SiCl₄ is used for the source of Si during the process of forming the CVD-SiN film 13, on the other hand, it can be seen from FIG. 8 that a leakage current density of 10⁸ A/cm² is realized even when the SiO₂-equivalent thickness of the CVD-SiN film 13 is reduced to 3.8 nm as represented by ●or ▪, wherein ● or ▪ in FIG. 8 represents the leakage current through a CVD-SiN film deposited at 680° C. while using SiCl₄ as the source of Si with different ratio for the partial pressure of SiCl₄ and NH₃.

It is noted that FIG. 8 further represents a data point ♦ corresponding to an SiN film characterized by the minimum leakage current among the SiN films having the SiO₂-equivalent thickness of 3.8 nm. In the SiN film represented by ♦, it is possible to reduce the thickness further when a leakage current having the leakage current density of 10⁻⁸ A/cm² is allowed.

Thus, the process of the present embodiment can provide an SiN film having a minimum leakage current density, by forming a thermal nitride film on the surface of the Si substrate 11 at 640° C., followed by a CVD process at 640° C. while supplying SiCl₄ and NH₃ as the source gases of Si and N. In the process of the present invention, it is also possible to use a polysilicon layer or amorphous silicon layer in place of the Si substrate 11. Further, a similar low-leakage SiN film is obtained also when the CVD process is conducted at 650° C.

When the temperature of the CVD process is decreased below 550° C., on the other hand, the reaction rate of the decomposition reaction of NH₃ and SiCl₄ in the reactor tube 11 becomes too sluggish for causing any material deposition of the SiN film. Thus, it is preferable to conduct the CVD process of the SiN film at the temperature between 550-650° C., preferably in the range between 600-640° C. Particularly, the deposition temperature of 640° C. is preferable for improving surface morphology of the deposited SiN film in view of the reduced deposition rate.

According to the present invention, the SiN film is formed at a relatively low temperature, and thus, there occurs no substantial modification in the distribution profile of impurity elements in the diffusion regions of active devices, which may be an ultrafine MOS transistor formed on the substrate, even in such a case the capacitor that uses the capacitor insulation film of SiN is formed on an interlayer insulation film that covers the ultrafine MOS transistor.

It should be noted that the SiN film 13 formed according to the temperature profile of FIG. 4 has a refractive index of 1.90±0.04, wherein this value of the refractive index is slightly smaller than the refractive index value of 2.0 for a normal or ordinary SiN film. Further, it should be noted that a normal SiO₂ film has a refractive index of about 1.42 and a normal SiON film has a refractive index of about 1.65.

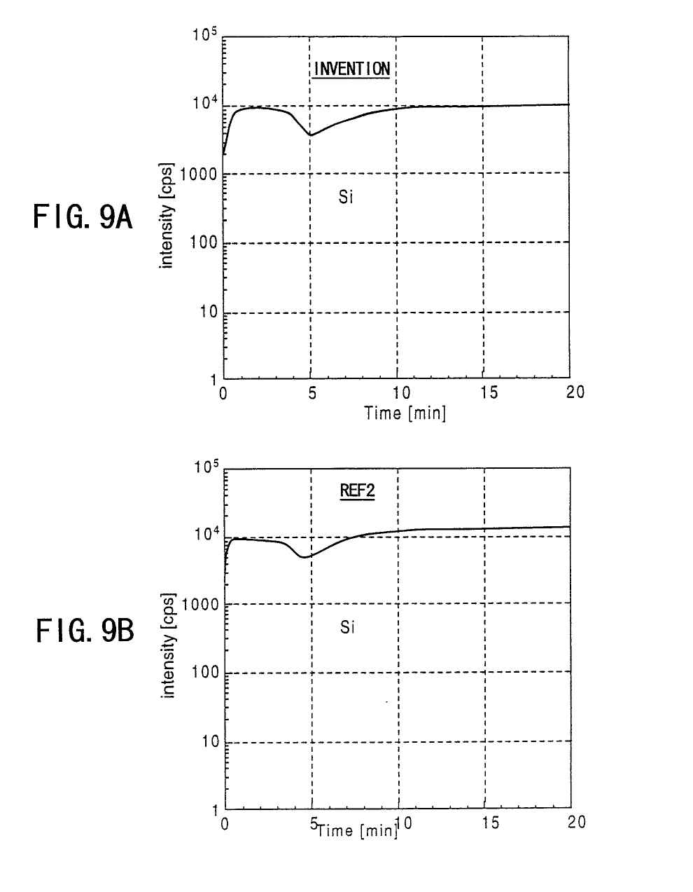

FIGS. 9A, 10A and 11A show the depth profile of Si, N and O atoms obtained by a SIMS analysis for the structure of FIG. 1C for the case the thermal nitride film 12A and the CVD-SIN film 13 are formed according to the temperature profile of FIG. 4 of the present invention. Further, FIGS. 9B, 10B and 11B show the depth profile of Si, N and O atoms, obtained also by a SIMS analysis for the structure of FIG. 1C for the case the thermal nitride film 12A and the CVD-SIN film 13 are formed according to the temperature profile of FIG. 6 for the second reference SiN film. In each of FIGS. 9A-11B, the vertical axis represents the SIMS intensity while the horizontal axis represents a depth as measured from the surface of the CVD-SiN film 13 in the structure of FIG. 1C. In each of FIGS. 9A-11B, it should be noted that the SIMS analysis was conducted in the state that the oxide film 14 represented in FIG. 7 is formed on the surface of the CVD-SiN film 13 by the wet-oxidation process.

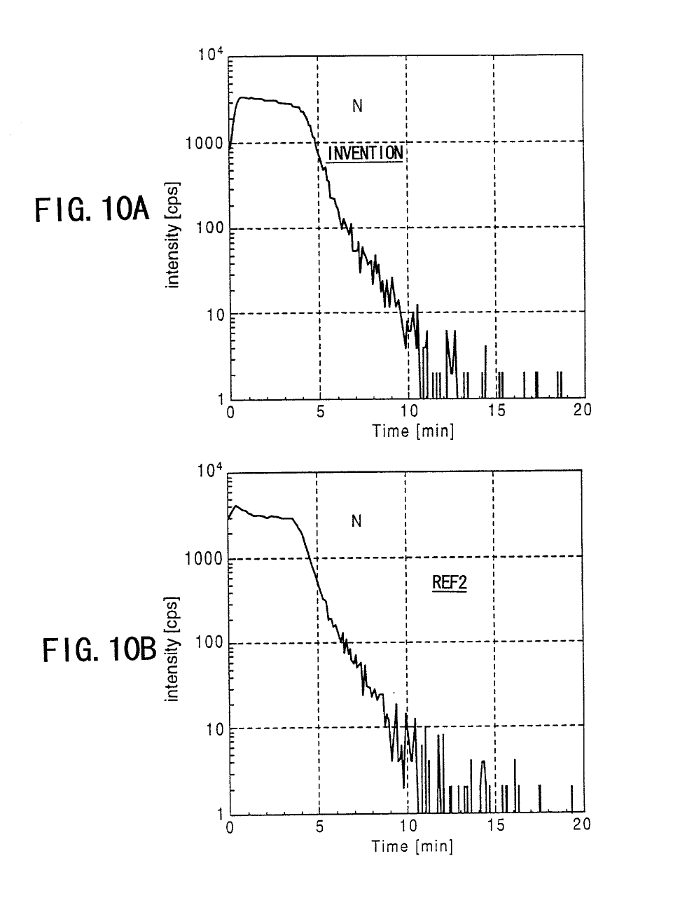

Referring to FIGS. 9A-10B, it should be noted that each of the specimen has a generally identical distribution profile for the Si and N atoms. In view of the fact that the SIMS intensity for the N atoms becomes substantially zero after 10 minutes from the start of the analysis, it will be understood that the foregoing depth, corresponding to the duration of 10 minutes, corresponds to the top surface of the Si substrate.

Referring to FIGS. 11A and 11B, it can be seen that the thermal nitride film 12A formed on the surface of the Si substrate is located at the depth corresponding to the SIMS duration of 5 minutes and that the thermal nitride film 12A is substantially free from oxygen. On the other hand, it can be seen that the CVD-SiN film 13 formed on the thermal nitride film 12A contains a substantial amount of oxygen in any of the specimens of FIGS. 11A and 11B.

Comparing the distribution profile of FIG. 11A with the distribution profile of FIG. 11B, it can be seen that the CVD-SiN film 13 of FIG. 11A contains a larger amount of oxygen atoms as compared with the CVD-SiN film 13 of FIG. 11B. It is believed that this is the reason why the CVD-SiN film 13 of the present invention has the lower refractive index of 1.90 as compared with the ordinary or normal refractive index of SiN of 2.0.

In the present invention, it is possible to use other ammoniac gas such as hydrazine for the source of N in place of NH₃.

[Second Embodiment]

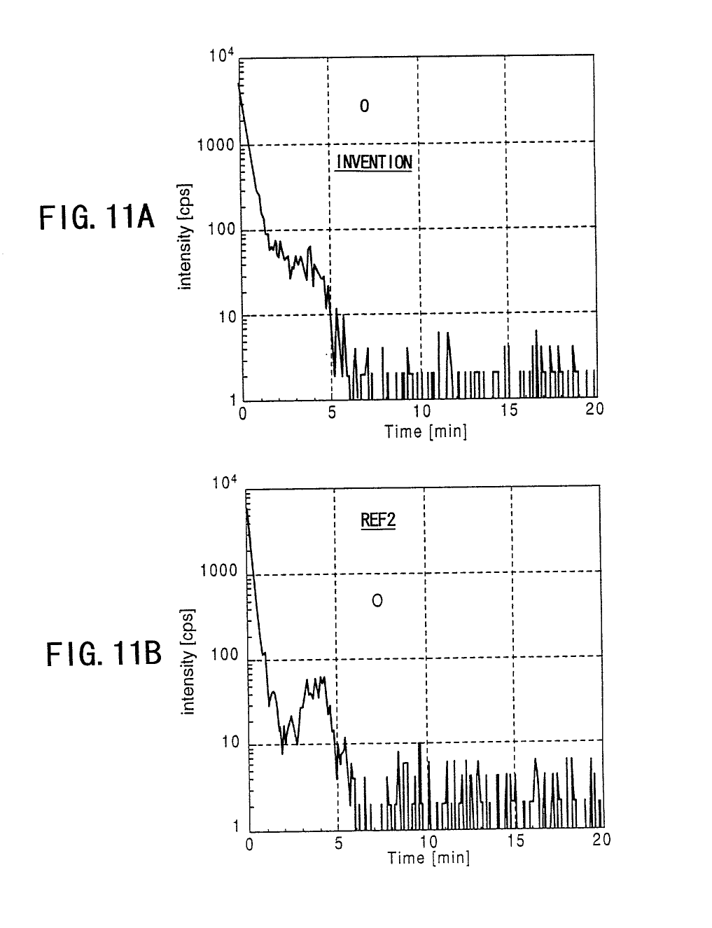

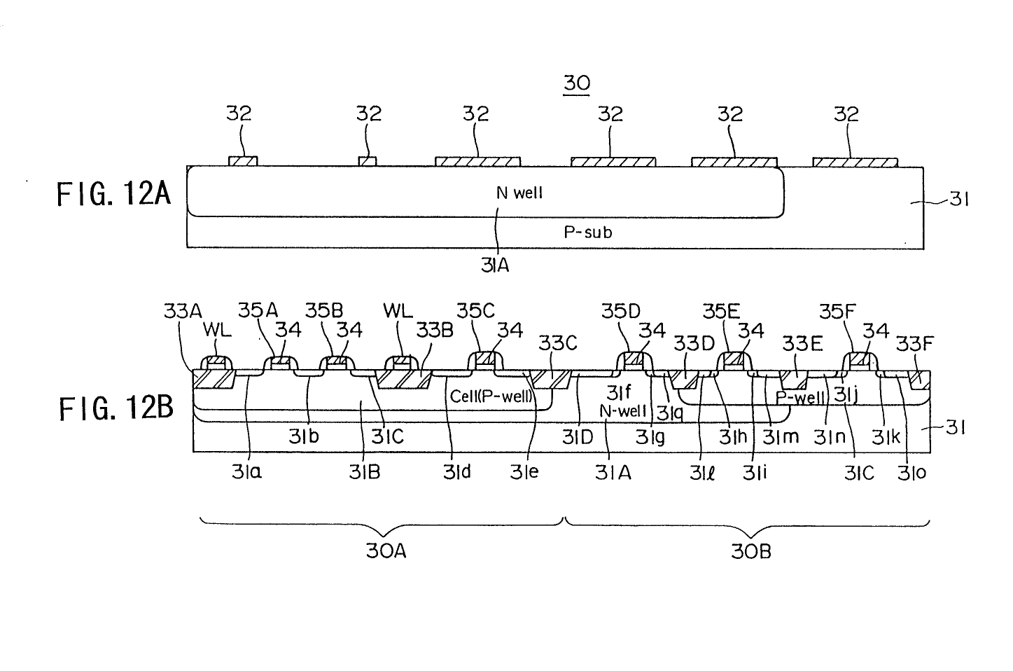

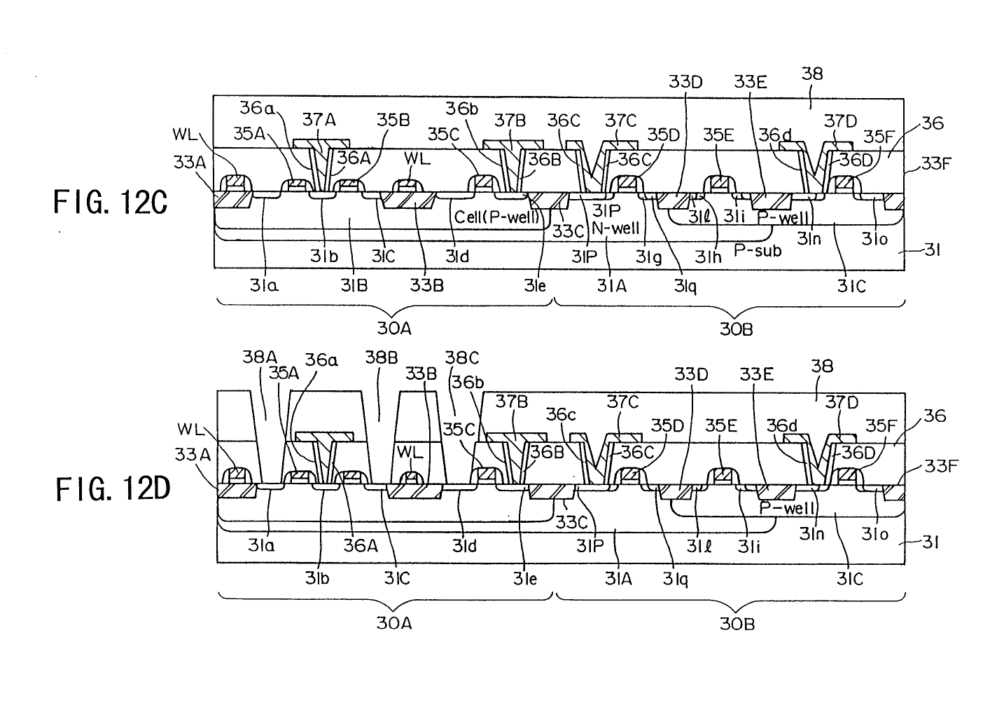

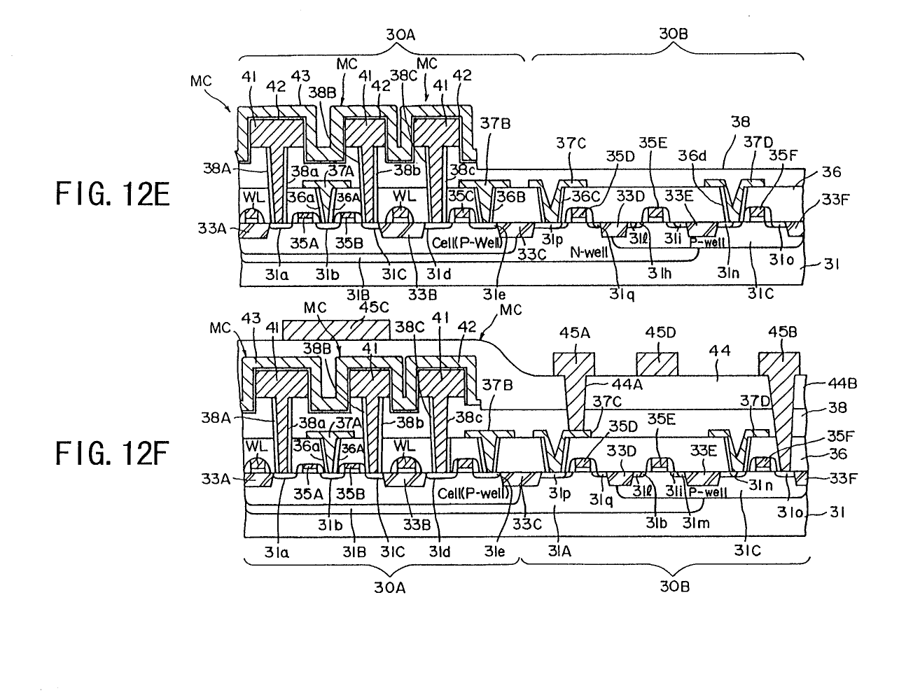

FIGS. 12A-12F show the fabrication process of a DRAM/logic hybrid integrated circuit 30 according to a second embodiment of the present invention.

Referring to FIG. 12A, a p-type Si substrate 31 is formed with an n-type well 31A and an initial oxide film (not shown) is formed on the substrate with a thickness of about 3 nm. Further, an SiN pattern 32 is formed thereon with a thickness of about 115 nm, such that the SiN pattern 32 defines a device isolation region.

Next, in the step of FIG. 12B, shallow-trench isolation structures 33A-33F are formed on the substrate 31 while using the SiN pattern 32 as a mask, and a p-type well 31B is formed in the n-type well 31A in correspondence to a memory cell region 30A by conducting an ion implantation process of B⁺. Further, there is formed a p-type well 31C in the substrate 31 in correspondence to a logic circuit region 30B formed outside the p-type well 31B, such that the p-type well 31C extends from the peripheral region 31B. In the actual process of forming the foregoing wells, the p-type well 31C may be formed first, followed by the step of forming the n-type well 31B. The n-type well 31A may be formed by an ion implantation process after the formation of the shallow-trench isolation regions.

Next, in the step of FIG. 12B, a gate oxide film 34 is formed on the surface of the substrate 31 with a thickness of about 8 nm by a thermal oxidation process, and an amorphous silicon layer doped with P is formed further on the gate oxide film 34 by a thermal CVD process with a thickness of about 160 nm. By patterning the amorphous silicon layer by a photolithographic process, gate electrodes 35A-35F are formed on the substrate 31 with a gate length of 0.18 μm or less. Thereby, each of the gate electrodes 35A-35F constitutes a part of the word line WL, as is well known in the art. Further, the shallow-trench isolation regions 33A and 33B in the memory cell region 30A carries thereon the word lines WL of different memory cell regions.

Further, an ion implantation process of P⁺ is conducted into the memory cell region 30A of the Si substrate 31 while using the gate electrodes 35A-35F as a mask, to form diffusion regions 31a-31d of the n⁻-type such that the diffusion regions 31a-35d are located adjacent to the gate electrodes 35A-35C. Simultaneously to the formation of the foregoing diffusion regions 31a-31d, diffusion regions 31h-31k of the n⁻-type are formed in the peripheral region 30B adjacent to the gate electrodes 35E and 35F, wherein the diffusion regions 31h-31k of the n⁻-type constitute an LDD region of the transistor to be formed in the logic circuit region 30B. Further, diffusion regions 31f and 31g of the n⁻-type are formed also in the n-type well 31A of the logic-circuit region 30B adjacent to the gate electrode 35D.

Next, the memory cell region 30A and the p-type well 31C are protected by a resist pattern and an ion implantation of B⁺ is conducted into the exposed n-type well region 31A of the logic-circuit region 30B while using the gate electrode 35D as a mask, and the conductivity type of the foregoing diffusion regions 31f and 31g is changed from the n⁻-type to the p⁻-type.

Further, the gate electrodes 35A-35F are covered by an oxide film, followed by an etch-back process, to form a sidewall oxide film on each of the gate electrodes 35A-35F.

Next, in the same step of FIG. 12B, the memory cell region 30A and the n-type well 31A of the logic-circuit region 30B are covered by a resist pattern, and diffusion regions 31l-31o of the n⁺-type are formed in the substrate 31 adjacent to the electrodes 35E and 35F at the location outside the sidewall oxide film thereon, by conducting an ion implantation process of As⁺ while using the gate electrodes 35E and 35F and the sidewall oxide films thereon as a self-aligned mask.

In the step of FIG. 12B, the substrate 31 is further covered by a resist pattern such that the n-type well 31A of the logic-circuit region 30B is exposed, and an ion implantation process of BF₂⁺ is conducted into the substrate 31 while using the gate electrode 35D and the sidewall oxide films thereon as a self-aligned mask, to form diffusion regions 31p and 31q of the p⁺-type adjacent to the gate electrode at the location outside the sidewall oxide films.

Next, in the step of FIG. 12C, a BPSG film 36 is deposited on the structure of FIG. 12B with a thickness of about 250 nm, and contact holes 36A-36D are formed in the BPSG film 36 so as to expose the foregoing diffusion regions 31b, 31e, 31p and 31n. Further, an oxide film is deposited on the BPSG film 36 by a thermal CVD process, followed by an etch-back process applied uniformly, to form sidewall oxide films 36a-36d on the sidewall of the contact holes 36A-36D, respectively. Further, electrodes 37A-37D, each formed of a stacking of an amorphous silicon pattern doped with P and a WSi pattern, are formed so as to cover the bottom surface of the contact holes 36A-36D, respectively. It should be noted that the electrodes 37A and 37B in the memory cell region 30B constitutes a bit line pattern. By forming the sidewall oxide films 36a-36d on the contact holes 36A-36D, the problem of short circuit, which tends to occur when the contact holes are formed at an offset location, between the electrode in the contact hole and the adjacent gate electrode is effectively eliminated.

In the step of FIG. 12C, another BPSG film 38 is formed on the foregoing BPSG film 36 with a thickness of about 350 nm, such that the BPSG film 38 covers the electrodes 37A-37D.

Next, in the step of FIG. 12D, contact holes 38A-38C are formed in the BPSG film 38 of FIG. 12C so as to expose the diffusion regions 31a, 31c and 31d of the memory cell region 30A respectively, followed by the step of FIG. 12E to form memory cell capacitors such that the memory cell capacitor covers each of the contact holes 38A-38C.

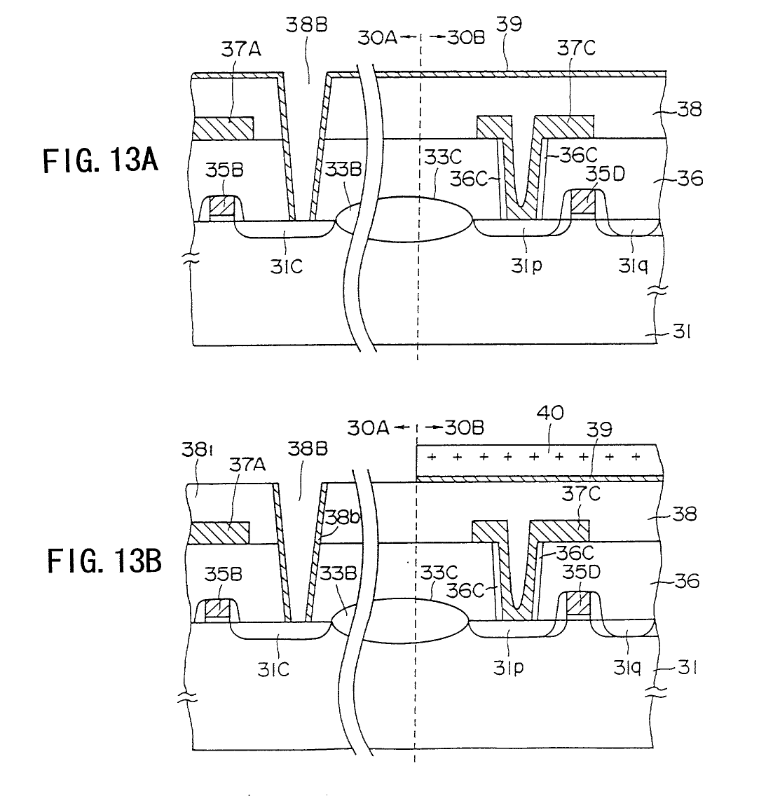

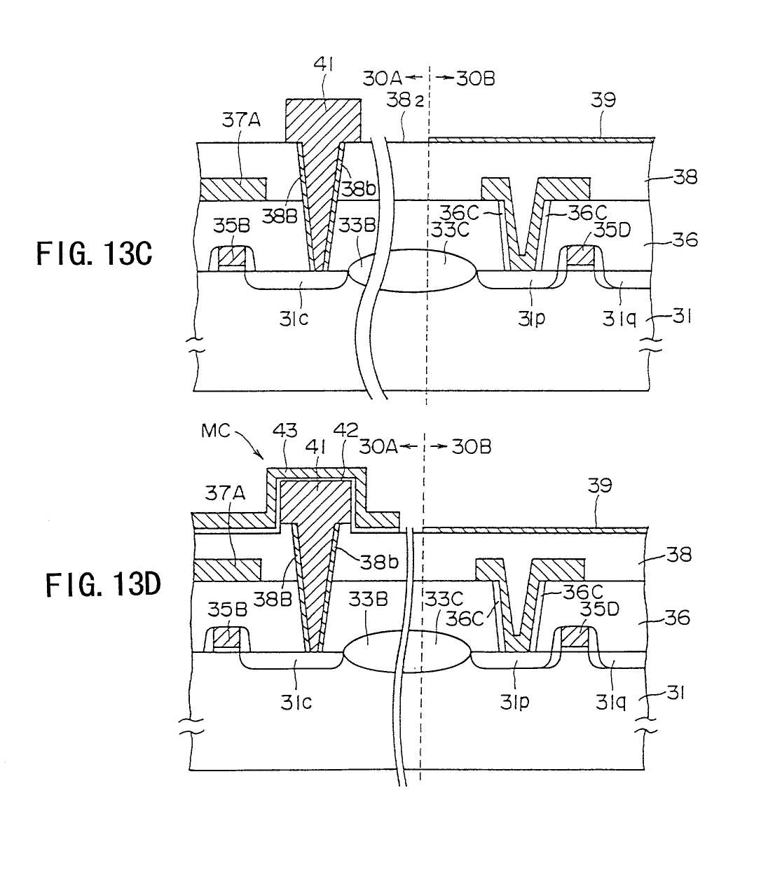

FIGS. 13A-13D show the process steps between the step of FIG. 12D and the step of FIG. 12E in detail, wherein those parts corresponding to the parts described previously are designated by the same reference numerals and the description thereof will be omitted.

Referring to FIG. 13A, the BPSG film 38 is covered by an insulation film 39 of the material having an etching rate smaller than the etching rate of the BPSG film 36 or 38, such as SiO₂, SiN or SiON, such that the insulation film 39 covers the contact hole 38B. By applying an etch-back process to the insulation film 39 thus formed, a sidewall insulation film 38b is formed such that the sidewall insulation film 38b covers the sidewall of the contact hole 38B as represented in FIG. 13B.

Next, in the step of FIG. 13C, the resist pattern 40 of FIG. 13B is removed and an amorphous silicon layer doped with P is deposited thereon. After patterning the amorphous silicon layer thus deposited, there is formed a storage electrode 41 forming a part of the memory cell capacitor such that the storage electrode 41 covers the contact hole 38B.

Next, in the step of FIG. 13D, a thermal nitridation process is applied to the surface of the amorphous silicon storage electrode 41 by conducting the process explained with reference to FIGS. 3 and 4, and a CVD-SiN film is deposited on the thermal nitride film thus formed by a low-pressure CVD process at 640° C. while using SiCl₄ and NH₃ as the sources of Si and N. As a result, there is formed an SiN capacitor insulation film 42 on the surface of the storage electrode 41.

The SiN capacitor insulation film 42 is further subjected to a thermal oxidation process, and an opposing electrode or cell-plate 43 is deposited on the SiN capacitor insulation film 42 thus formed by depositing an amorphous silicon layer doped with P. Subsequently, the opposing electrode 43 is subjected to a patterning process. It should be noted that the structure of FIG. 13D corresponds to the structure of FIG. 12E.

Thus, referring back to FIG. 12E, it can be seen that there is formed a memory cell capacitor MC including the storage electrode 41, the capacitor dielectric film 42 and the opposing electrode, in each of the contact holes 38A, 38B and 38C that are formed in the BPSG film 38 so as to expose the diffusion regions 31a, 31c and 31d.

Next, in the step of FIG. 12F, a BPSG film 44 is formed on the structure of FIG. 12E with a thickness of about 350 nm, and interconnection electrodes 45A and 45B are formed on the BPSG film 44 so as to make an electrical contract with the electrode 37C and the diffusion region 310 via respective contact holes 44A and 44B. Further, interconnection patterns 45C and 45D are formed on the BPSG film 44.

In the DRAM/logic hybrid integrated circuit 30 of the present embodiment, the leakage characteristic of the SiN capacitor insulation film 42 is improved substantially, and the memory cell capacitor MC can achieve a reliable retention of information even in such a case in which the thickness of the capacitor insulation film 42 is less than 4.0 nm in terms of the SiO₂-equivalent thickness. Thus, the present invention enables increase of the capacitance of the memory cell capacitor MC by decreasing the thickness of the SiN capacitor insulation film 42.

According to the present invention, the process of forming the capacitor insulation film 42 is conducted at the low temperature lower than 650° C. as noted before. Thus, there occurs no change of impurity concentration profile in the diffusion regions 31a-31o. As noted with reference to the previous embodiment, the SiN capacitor insulation film 42 thus formed has a refractive index of about 1.90.

It should be noted that the SiN film used in the present invention may contain substantial amount of other element such as oxygen, in addition to Si and N.

Further, the present invention is not limited to the embodiments described heretofore, but various variations and modifications may be made without departing from the scope of the invention.

What is claimed is:

1. A semiconductor device, comprising:
a substrate;
a device formed on said substrate; and
a capacitor formed on said substrate in electrical connection with said device,
said capacitor having a capacitor insulation film of SiN having a refractive index of approximately 1.90.

2. A semiconductor device as claimed in claim 1, wherein said capacitor insulation film has an SiO₂-equivalent thickness of 4.0 nm or less.

3. A semiconductor device as claimed in claim 1, wherein said capacitor includes a lower electrode of Si, and wherein said capacitor insulation film of SiN is formed directly on said lower electrode.

4. A semiconductor device as claimed in claim 1, wherein said capacitor includes a lower electrode of Si, and wherein said capacitor insulation film of SiN is formed on said lower electrode via an SiO₂ film.

5. A semiconductor device as claimed in claim 1, wherein said device has a gate length of 0.18 μm or less.

6. A method of fabricating a semiconductor device having a substrate carrying thereon a device and a capacitor, comprising the steps of:
forming a first SiN film on a surface of a Si pattern constituting a lower electrode of said capacitor by applying a thermal nitridation process to said surface of said Si pattern as a part of a capacitor insulation film of said capacitor;
forming a second SiN film on a surface of said first SiN film as a part of said capacitor insulation film, by conducting a CVD process that uses a reaction of SiCl₄ and an ammoniac gas,
wherein said CVD process is conducted at a temperature in the range of 550-660° C.

7. A method as claimed in claim 6, wherein said CVD process is conducted while supplying SiCl₄ and NH₃ with respective flow-rates A and B with a ratio satisfying the relationship of A:B=1:1-1:5.

8. A method as claimed in claim 7, wherein said CVD process is conducted at a temperature of 600-640° C.

9. A method of forming an SiN film, comprising the steps of:
forming a first SiN film on a surface of a Si substrate by applying a thermal nitridation process to said surface of said Si substrate;
forming a second SiN film on a surface of said first SiN film by conducting a CVD process that uses a reaction of SiCl₄ and an ammoniac gas,
wherein said CVD process is conducted at a temperature in the range of 550-660° C.

10. A method as claimed in claim 9, wherein said CVD process is conducted while supplying SiCl₄ and NH₃ with respective flow-rates A and B with a ratio satisfying the relationship of A:B=1:1-1:5.

11. A method as claimed in claim 9, wherein said CVD process is conducted at a temperature of 600-640° C.
